(19) United States
(12) Patent Application Publication
(10) Pub. No.: US 2024/0039509 A1
(43) Pub. Date: Feb. 1, 2024

(54) Vibrator Element, Vibrator Device, And Method For Manufacturing Vibrator Element

(71) Applicant: SEIKO EPSON CORPORATION, Tokyo (JP)

(72) Inventors: Kensaku ISOHATA, Minowa (JP); Atsushi MATSUO, Shiojiri (JP); Norihito MATSUKAWA, Shimosuwa (JP)

(21) Appl. No.: 18/360,341

(22) Filed: Jul. 27, 2023

(30) Foreign Application Priority Data
Jul. 28, 2022 (JP) 2022-120266

(51) Int. Cl. H03H 9/05; H03H 3/02; H03H 9/10; H03H 9/19

(52) U.S. Cl. CPC H03H 9/0595; H03H 3/02; H03H 9/1021; H03H 9/19; H03H 2003/022

(57) ABSTRACT

A vibrator element includes a vibrator section that has a first principal surface, a second principal surface, a first side surface, and a second side surface, a support section that is disposed at a distance from the vibrator section and has a first support side surface facing the first side surface of vibrator section and a second support side surface extending in a direction that intersects with the direction in which the first support side surface extends, and a linkage section that has a first linkage surface coupled to the first side surface and the first support side surface and a second linkage surface coupled to the second side surface and the second support side surface, and the first linkage surface has a configuration in which at least one of a first section coupled to the first side surface and a second section coupled to the first support side surface has a curved surface.

The present application is based on, and claims priority from JP Application Serial Number 2022-120266, filed Jul. 28, 2022, the disclosure of which is hereby incorporated by reference herein in its entirety.

### BACKGROUND

### 1. Technical Field

The present disclosure relates to a vibrator element, a vibrator device, and a method for manufacturing the vibrator element.

### 2. Related Art

JP-A-2015-186196 discloses the configuration of a piezoelectric vibrator element including a vibrator section provided with a pair of excitation electrodes, a support section extending away from the vibrator section, and a linkage section extending to link one end of the support section to the end of the vibrator section, with draw-out electrodes respectively drawn from the pair of excitation electrodes to a joint surface of the support section so that the effect of support stress on the vibration is suppressed.

In the technology described in JP-A-2015-186196, however, in which the linkage section is shifted to one side of the vibrator element, when an external shock is applied to the vibrator element, the resultant stress concentrates in the inner right-angled portion of the linkage section, the stress concentration may cause the piezoelectric vibrator element to crack or break.

### SUMMARY

A vibrator element includes a vibrator section that has a first principal surface, a second principal surface that is opposite from the first principal surface, a first side surface that couples the first principal surface and the second principal surface to each other, a second side surface that extends in a direction that intersects with a direction in which the first side surface extends; a support section that is disposed at a distance from the vibrator section and has a first support side surface facing the first side surface of the vibrator section and a second support side surface extending in a direction that intersects with a direction in which the first support side surface extends; and a linkage section that has a first linkage surface coupled to the first side surface and the first support side surface and a second linkage surface coupled to the second side surface and the second support side surface, and the first linkage surface has a configuration in which at least one of a first section coupled to the first side surface and a second section coupled to the first support side surface has a curved surface.

A vibrator device includes the vibrator element described above, a base on which the vibrator element is mounted, and a container that houses the vibrator element, and the support section of the vibrator element is joined to the base via a joining material.

A method for manufacturing a vibrator element includes preparing a substrate, forming a protective film that constitutes an outer shape pattern at the substrate, and etching the substrate by using the protective film as a mask to form a vibrator element having an outer shape corresponding to the outer shape pattern. The vibrator element includes a vibrator section that has a first principal surface, a second principal surface that is opposite from the first principal surface, a first side surface that couples the first principal surface and the second principal surface to each other, a second side surface that extends in a direction that intersects with a direction in which the first side surface extends, a support section that is disposed at a distance from the vibrator section and has a first support side surface facing the first side surface of the vibrator section and a second support side surface extending in a direction that intersects with a direction in which the first support side surface extends, and a linkage section that has a first linkage surface coupled to the first side surface and the first support side surface and a second linkage surface coupled to the second side surface and the second support side surface, and the first linkage surface has a configuration in which at least one of a first section coupled to the first side surface and a second section coupled to the first support side surface has a curved surface.

### BRIEF DESCRIPTION OF THE DRAWINGS

FIG. 1 is a plan view showing the configuration of a vibrator device.

FIG. 2 is a cross-sectional view of the vibrator device shown in FIG. 1 taken along the line A-A.

FIG. 3 is a plan view showing the configuration of a vibrator element.

FIG. 4 is a cross-sectional view of the vibrator element shown in FIG. 3 taken along the line B-B.

FIG. 5 is a flowchart showing a method for manufacturing the vibrator element.

FIG. 6 is a plan view showing the configuration of a vibrator element according to a variation.

FIG. 7 is a plan view showing the configuration of a vibrator element according to another variation.

FIG. 8 is a plan view showing the configuration of a vibrator element according to another variation.

FIG. 9 is a plan view showing the configuration of a vibrator element according to another variation.

FIG. 10 is a plan view showing the configuration of a vibrator element according to another variation.

### DESCRIPTION OF EXEMPLARY EMBODIMENTS

In the following drawings, the description will be made by using three axes called axes X, Y, and Z perpendicular to one another. The direction along the axis X is called a “direction X”, the direction along the axis Y is called a “direction Y”, and the direction along the axis Z is called a “direction Z”, with the direction indicated by the arrow is the direction toward the positive end of the axis, and the direction opposite the direction toward the positive end is the direction toward the negative end of the axis. The direction toward the positive end of the direction Z is also called “upper” or “upward”, and the direction toward the negative end of the direction Z is also called “lower” or “downward” in some cases, and views in the directions toward the positive and negative ends of the direction Z are each also called a plan view or planar. The description will be made on the assumption that a surface facing the positive end of the direction Z is called an upper surface, and that a surface facing the negative end of the direction Z, which is a surface opposite from the upper surface, is called a lower surface.

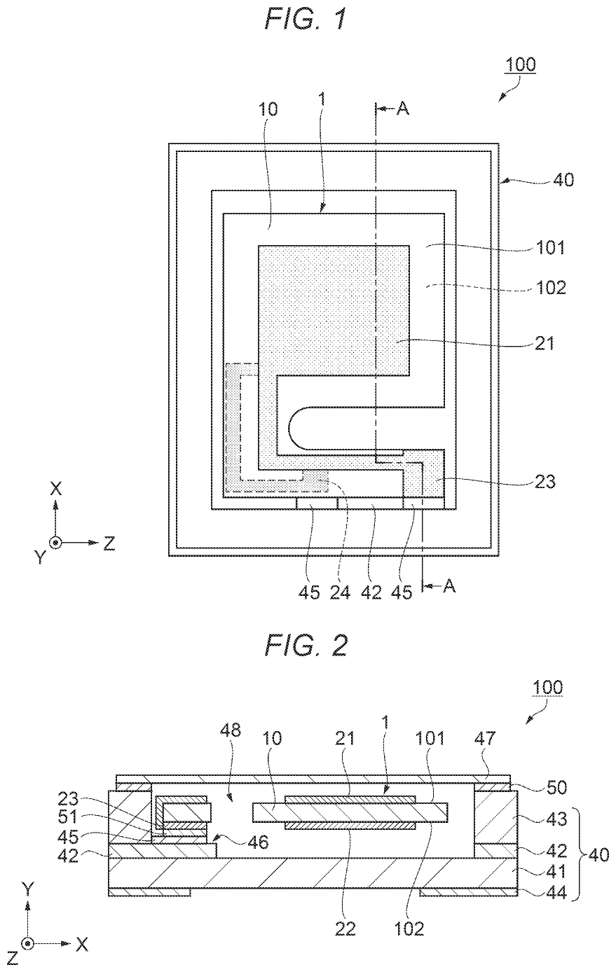

The configuration of a vibrator device 100 will first be described with reference to FIGS. 1 and 2. A lid 47 is omitted in FIG. 1 for convenience of the description.

The vibrator device 100 includes a vibrator 1, a container 40, which is made of ceramic or any other material and houses the vibrator 1, and a lid 47 made of glass, ceramic, metal, or any other material, as shown in FIGS. 1 and 2.

The container 40 is formed by stacking an implementation terminal 44, a first substrate 41, a second substrate 42, and a third substrate 43 on each other, as shown in FIG. 2. In the present embodiment, the second substrate 42 is a base on which a vibrator element 10, that is, the vibrator 1, is mounted.

The container 40 has a cavity 48, which opens upward. The interior of the cavity 48, which houses the vibrator 1, is hermetically sealed in the form of a reduced-pressure atmosphere or an inert gas atmosphere, such as a nitrogen atmosphere, when the lid 47 is joined to the container 40 via a joining member 50, such as a sealing ring.

The implementation terminal 44 is actually formed of a plurality of implementation terminals 44 provided at the outer bottom surface of the first substrate 41. The implementation terminals 44 are electrically coupled to coupling terminals 45, which are provided on the second substrate 42, via through-via electrodes and interlayer wiring lines that are not shown.

The vibrator 1 is housed in the cavity 48 of the container 40. In the vibrator 1, mount electrodes 23 and 24, which are provided at a support section 120 (see FIG. 3), are joined and electrically coupled to the coupling terminals 45, which are provided at a mounting surface 46 of the second substrate 42, which is the base, via a joining material 51, such as an electrically conductive adhesive.

The joining material 51 includes a first electrically conductive adhesive and a second electrically conductive adhesive. The first electrically conductive adhesive electrically couples a first excitation electrode 21 to the second substrate 42. The second electrically conductive adhesive electrically couples a second excitation electrode 22 to the second substrate 42. That is, the excitation electrodes 21 and 22 of the vibrator 1 and the implementation terminals 44 provided at the container 40 are electrically coupled to each other via the mount electrodes 23 and 24, the joining material 51, the coupling terminals 45, and other components.

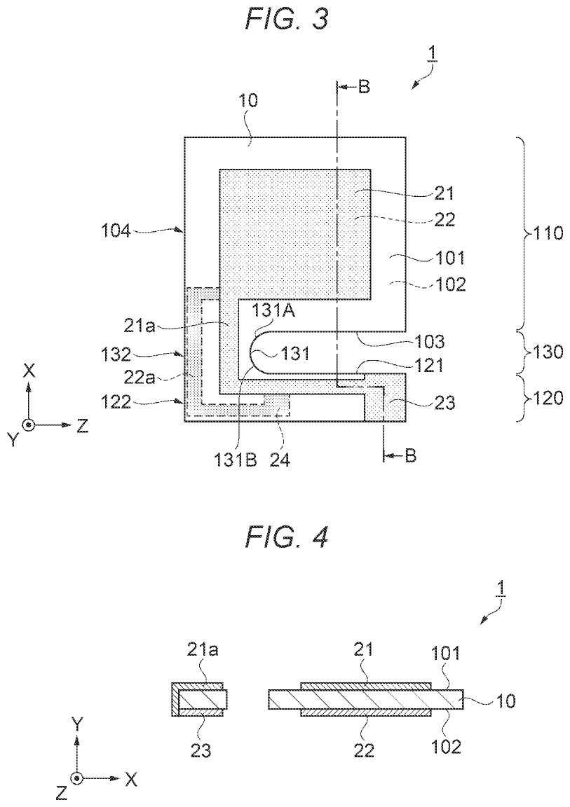

The configuration of the vibrator 1 will next be described with reference to FIGS. 3 and 4.

The vibrator 1 includes the vibrator element 10, the first excitation electrode 21, the second excitation electrode 22, the first mount electrode 23, and the second mount electrode 24, as shown in FIGS. 3 and 4.

The vibrator element 10 is capable of thickness-shear vibration and is made of any of a variety of piezoelectric materials, including a quartz crystal element as a representative example. The vibrator element 10 is typically an AT-cut quartz crystal element, or a two-turn-cut quartz crystal element, a representative example of which is an SC-cut quartz crystal element. In the present embodiment, the vibrator element 10 is an AT-cut quartz crystal element having a quadrangular planar shape, specifically, an oblong planar shape. The directions toward the positive ends of the axes X, Y, and Z in FIGS. 3 and 4 therefore coincide with the directions toward the positive ends of axes Z′, X, and Y′ that are the crystallographic axes of quartz crystal, respectively. The definition described above is not necessarily employed, and the direction toward the positive end of at least one of the axes X, Y, and Z may coincide with the direction toward the negative end.

The vibrator element 10 is a rectangular planar plate having a lengthwise direction that coincides with the direction Y and a widthwise direction that coincides with the direction X. The vibrator element 10 includes a vibrator section 110, the support section 120, which is disposed at a distance from the vibrator section 110, and a linkage section 130, which links the vibrator section 110 to the support section 120.

The vibrator section 110 has a first principal surface 101, a second principal surface 102, which is opposite from the first principal surface 101, a first side surface 103, which couples the first principal surface 101 and the second principal surface 102 to each other, and a second side surface 104, which extends along a direction that intersects with the direction in which the first side surface 103 extends.

The support section 120 has a first support side surface 121 disposed so as to face the first side surface 103 of the vibrator section 110, and a second support side surface 122 extending in a direction that intersects with the direction in which the first support side surface 121 extends.

The linkage section 130 has a first linkage surface 131 coupled to the first side surface 103 and the first support side surface 121, and a second linkage surface 132 coupled to the second side surface 104 and the second support side surface 122.

The first linkage surface 131 has a configuration in which at least one of a first section 131A coupled to the first side surface 103 and a second section 131B coupled to the first support side surface 121 has a curved surface. In the present embodiment, the first section 131A and the second section 131B each have a curved surface.

Since the first section 131A and the second section 131B each have a curved surface as described above, an external shock acting on the vibrator element 10 does not cause a situation in which the resultant stress concentrates only in a certain portion of the first section 131A and the second section 131B. That is, stress concentration does not occur, but the stress can be dispersed, whereby cracking of or damage to the vibrator element 10 can be suppressed.

The first excitation electrode 21 is provided substantially at the center of the first principal surface 101 of the vibrator element 10. The second excitation electrode 22 is provided substantially at the center of the second principal surface 102 of the vibrator element 10 so as to coincide with the first excitation electrode 21 in the plane view.

The first excitation electrode 21 is electrically coupled to the first mount electrode 23 via a first lead electrode 21a. The second excitation electrode 22 is electrically coupled to the second mount electrode 24 via a second lead electrode 22a. The first mount electrode 23 is electrically coupled to the first lead electrode 21a, for example, via a through-via electrode provided through the vibrator element 10.

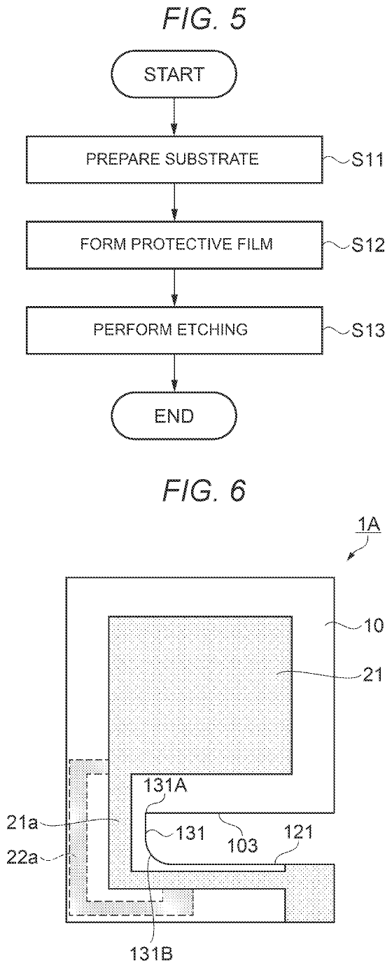

A method for manufacturing the vibrator element 10, which constitutes the vibrator 1, will next be described with reference to FIG. 5.

First, in step S11, a substrate that later forms the vibrator element 10 is prepared, as shown in FIG. 5. The substrate is made of a piezoelectric material, and is typically, for example, an AT-cut crystal quartz substrate or an SC-cut crystal quartz substrate.

Thereafter, in step S12, a protective film is formed on the substrate. A metal film made, for example, of gold is first deposited over the entire surface of the substrate by using a sputtering or vapor deposition apparatus. Note that the metal film functions as a protective film that protects the substrate in an etching process that will be described later.

A photoresist is then applied onto the entire surface of the substrate on which the metal film has been deposited by using a spray- or spin-type photoresist applicator. A photomask is then placed on the substrate onto which the photoresist has been applied and is exposed to light. The photoresist is developed, and the metal film exposed via the photoresist is etched to form a protective film that constitutes an outer shape pattern of the vibrator element 10.

Thereafter, in step S13, the protective film is used as a mask, and the etching process using dry etching is performed on the exposed portions of the substrate excluding the outer shape pattern, for example, by using a reactive ion etcher to form the vibrator element 10. Since dry etching is used, the crystalline surface of the substrate is less likely to be exposed, for example, than in a case where wet etching is used, so that the resultant shape more closely reflects the outer shape pattern, and stress concentration only in a certain portion of the first section 131A or the second section 131B can be further avoided. Note that the dry etching may be replaced with wet etching.

Carrying out the steps described above results in completion of the vibrator element 10 including the vibrator section 110, which has the first principal surface 101, the second principal surface 102, which is opposite from the first principal surface 101, the first side surface 103, which couples the first principal surface 101 and the second principal surface 102 to each other, and the second side surface 104, which extends in a direction that intersects with the direction in which the first side surface 103 extends, the support section 120, which is disposed at a distance from the vibrator section 110 and has the first support side surface 121 facing the first side surface 103 of the vibrator section 110 and the second support side surface 122 extending in a direction that intersects with the direction in which the first support side surface 121 extends, and the linkage section 130, which has the first linkage surface 131 coupled to the first side surface 103 and the first support side surface 121 and the second linkage surface 132 coupled to the second side surface 104 and the second support side surface 122, and the first linkage surface 131 has a configuration in which the first section 131A coupled to the first side surface 103 and the second section 131B coupled to the first support side surface 121 each have a curved surface.

As described above, the vibrator element 10 according to the present embodiment includes the vibrator section 110, which has the first principal surface 101, the second principal surface 102, which is opposite from the first principal surface 101, the first side surface 103, which couples the first principal surface 101 and the second principal surface 102 to each other, and the second side surface 104, which extends in a direction that intersects with the direction in which the first side surface 103 extends, the support section 120, which is disposed at a distance from the vibrator section 110 and has the first support side surface 121 facing the first side surface 103 of the vibrator section 110 and the second support side surface 122 extending in a direction that intersects with the direction in which the first support side surface 121 extends, and the linkage section 130, which has the first linkage surface 131 coupled to the first side surface 103 and the first support side surface 121 and the second linkage surface 132 coupled to the second side surface 104 and the second support side surface 122, and the first linkage surface 131 has a configuration in which at least one of the first section 131A coupled to the first side surface 103 and the second section 131B coupled to the first support side surface 121 has a curved surface.

According to the configuration described above, since the first section 131A or the second section 131B has a curved surface as described above, an external shock acting on the vibrator element 10 does not cause a situation in which the resultant stress concentrates only in a certain portion of the first section 131A or the second section 131B. That is, stress concentration does not occur, but the stress can be dispersed, whereby cracking of or damage to the vibrator element 10 can be suppressed.

In the vibrator element 10 according to the present embodiment, it is preferable that the first linkage surface 131 has a configuration in which the first section 131A and the second section 131B each have a curved surface. According to the configuration described above, since the first section 131A and the second section 131B each have a curved surface as described above, an external shock acting on the vibrator element 10 does not cause a situation in which the resultant stress concentrates only in a certain portion of the first section 131A and the second section 131B, whereby cracking of or damage to the vibrator element 10 can be further suppressed.

The vibrator device 100 according to the present embodiment includes the vibrator element 10 described above, the second substrate 42, on which the vibrator element is mounted, and the container 40, which houses the vibrator element 10, and the support section 120 of the vibrator element 10 is joined to the second substrate 42 via the joining material 51.

According to the configuration described above, a vibrator device 100 that does not crack or is not damaged even when an external shock acts thereon can be provided.

In the vibrator device 100 according to the present embodiment, the joining material 51 preferably includes the first electrically conductive adhesive, which electrically couples the first excitation electrode 21 provided at the first principal surface 101 to the second substrate 42, and the second electrically conductive adhesive, which electrically couples the second excitation electrode 22 provided at the second principal surface 102 to the second substrate 42. According to the configuration described above, since the joining material 51 includes the first electrically conductive adhesive and the second electrically conductive adhesive, electrical transmission from the first excitation electrode 21 and the second excitation electrode 22 to an external component and electrical reception from the external component can be performed.

The method for manufacturing the vibrator element 10 according to the present embodiment includes preparing a substrate, forming a protective film that constitutes an outer shape pattern at the substrate, and etching the substrate by using the protective film as a mask to form the vibrator element 10 having an outer shape corresponding to the outer shape pattern, the vibrator element 10 includes the vibrator section 110, which has the first principal surface 101, the second principal surface 102, which is opposite from the first principal surface 101, the first side surface 103, which couples the first principal surface 101 and the second principal surface 102 to each other, and the second side surface 104, which extends in a direction that intersects with the direction in which the first side surface 103 extends, the support section 120, which is disposed at a distance from the vibrator section 110 and has the first support side surface 121 facing the first side surface 103 of the vibrator section 110 and the second support side surface 122 extending in a direction that intersects with the direction in which the first support side surface 121 extends, and the linkage section 130, which has the first linkage surface 131 coupled to the first side surface 103 and the first support side surface 121 and the second linkage surface 132 coupled to the second side surface 104 and the second support side surface 122, and the first linkage surface 131 has a configuration in which at least one of the first section 131A coupled to the first side surface 103 and the second section 131B coupled to the first support side surface 121 has a curved surface.

According to the method described above, since the first section 131A or the second section 131B of the formed vibrator element 10 has a curved surface, an external shock acting on the vibrator element 10 does not cause a situation in which the resultant stress concentrates only in a certain portion of the first section 131A or the second section 131B, that is, stress concentration does not occur but the stress can be dispersed, whereby cracking of or damage to the vibrator element 10 can be suppressed.

In the method for manufacturing the vibrator element 10 according to the present embodiment, the etching process is preferably dry etching. According to the method described above, since dry etching is used, the crystalline surface of the substrate is less likely to be exposed, for example, than in a case where wet etching is used, so that the resultant shape more closely reflects the outer shape pattern, and stress concentration only in a certain portion of the first section 131A or the second section 131B can be further avoided.

Variations of the embodiment described above will be described below.

The configuration described above in which the first section 131A and the second section 131B of the first linkage surface 131 each have a curved surface is not necessarily employed, and the configurations shown in FIGS. 6 to 10 may be employed.

In the vibrator element 10 of a vibrator 1A according to a variation, the first section 131A is not curved but is angled, as shown in FIG. 6. Specifically, the first linkage surface 131 is formed so as to intersect with the first side surface 103 by a predetermined angle. The second section 131B is curved, as in the embodiment described above.

According to the configuration described above, the first linkage surface 131 intersects with the first side surface 103 by a predetermined angle, that is, the planar portion of the first section 131A that faces the vibrator section 110 is coupled to another planar portion at an angle therebetween, so that reflection of the vibration can be suppressed, whereby deterioration in the characteristic quality of the vibrator element 10 can be suppressed. Furthermore, since the second section 131B is curved, stress concentration at the second section 131B can be suppressed.

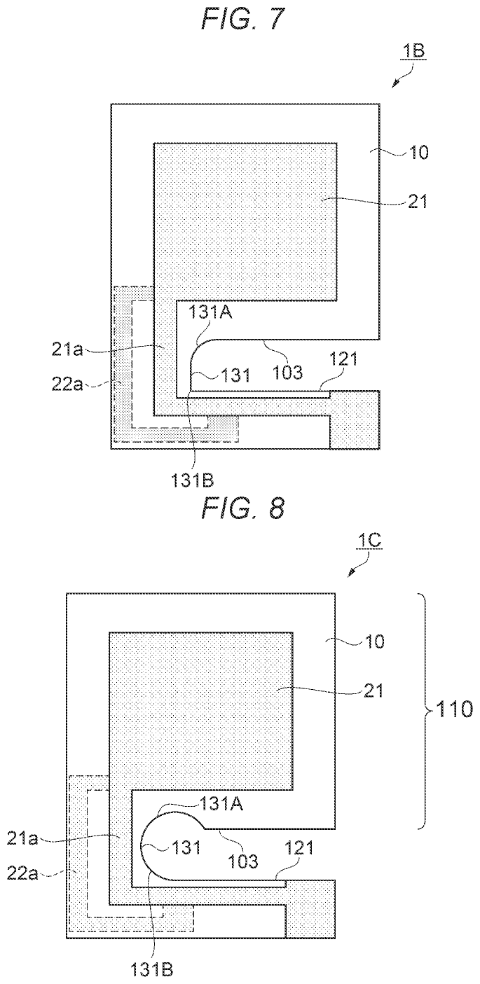

The first section 131A may be curved, and the second section 131B may be angled, as in the vibrator element 10 of a vibrator 1B according to a variation shown in FIG. 7.

The vibrator element 10 of a vibrator 1C according to a variation has a configuration in which the first section 131A of the first linkage surface 131 has a curved shape with part of the vibrator section 110 cut off, as shown in FIG. 8. The second section 131B is curved, as in the embodiment described above.

According to the configuration described above, since the first section 131A is so shaped that part of the vibrator section 110 cut off, an external shock acting on the vibrator element 10 does not cause a situation in which the resultant stress concentrates only in a certain portion of the first section 131A, whereby cracking of or damage to the vibrator element 10 can be further suppressed.

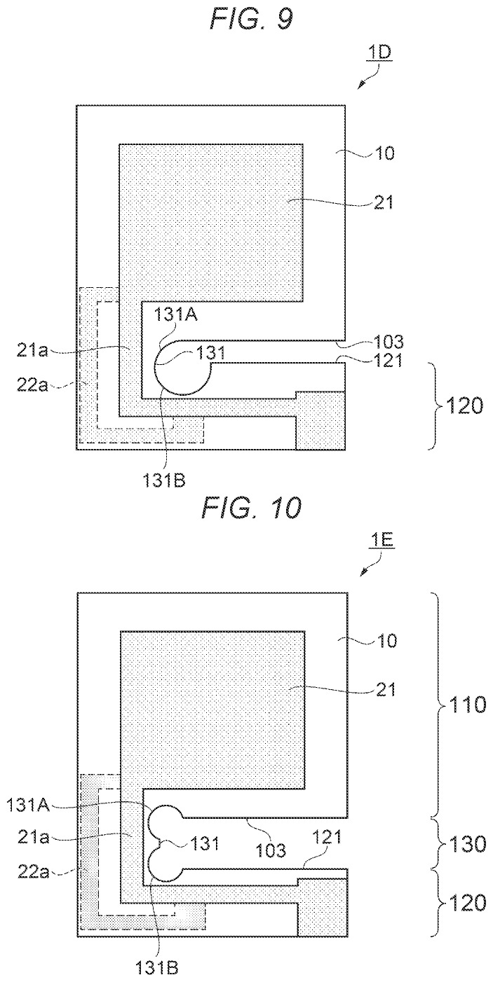

The second section 131B of the first linkage surface 131 may have a curved shape with part of the support section 120 cut off, as in the vibrator element 10 of a vibrator 1D according to a variation shown in FIG. 9. As in the vibrator element 10 of a vibrator 1E according to a variation shown in FIG. 10, the first section 131A may have a curved shape with part of the vibrator section 110 cut off, and the second section 131B may have a curved shape with part of the support section 120 cut off.

The vibrator element 10 described above is not necessarily so shaped that the vibrator section 110, the support section 120, and the linkage section 130 are provided, in other words, the vibrator 1 is so shaped that a slit is formed at one side, and the vibrator 1 may have two slits facing the center of the linkage section 130, that is, at the opposite sides of the vibrator 1.

In the vibrator element 10, the vibrator section 110, the support section 120, and the linkage section 130 do not necessarily have the same thickness. In particular, the first linkage surface 131, the first section 131A and the second section 131B may have different thicknesses depending on the strength and characteristic quality of the vibrator element 10.

What is claimed is:

1. A vibrator element comprising:
a vibrator section that has a first principal surface, a second principal surface that is opposite from the first principal surface, a first side surface that couples the first principal surface and the second principal surface to each other, and a second side surface that extends in a direction that intersects with a direction in which the first side surface extends;
a support section that is disposed at a distance from the vibrator section and has a first support side surface facing the first side surface of the vibrator section and a second support side surface extending in a direction that intersects with a direction in which the first support side surface extends; and
a linkage section that has a first linkage surface coupled to the first side surface and the first support side surface and a second linkage surface coupled to the second side surface and the second support side surface,
wherein the first linkage surface has a configuration in which at least one of a first section coupled to the first side surface and a second section coupled to the first support side surface has a curved surface.

2. The vibrator element according to claim 1,
wherein the first linkage surface has a configuration in which both of the first section and the second section have a curved surface.

3. The vibrator element according to claim 1,
wherein the first linkage surface has a configuration in which the second section has a curved surface, and is coupled to the first side surface at a predetermined angle.

4. The vibrator element according to claim 1,
wherein the first section of the first linkage surface is so shaped that part of the vibrator section cut off.

5. The vibrator element according to claim 1,
wherein the second section of the first linkage surface is so shaped that part of the support section cut off.

6. A vibrator device comprising:
the vibrator element according to claim 1;
a base on which the vibrator element is mounted; and
a container that houses the vibrator element,
wherein the support section of the vibrator element is joined to the base via a joining material.

7. The vibrator device according to claim 6,
wherein the joining material includes a first electrically conductive adhesive that electrically couples a first excitation electrode provided at the first principal surface to the base, and a second electrically conductive adhesive that electrically couples a second excitation electrode provided at the second principal surface to the base.

8. A method for manufacturing a vibrator element, the method comprising:
preparing a substrate;
forming a protective film that constitutes an outer shape pattern at the substrate; and
etching the substrate by using the protective film as a mask to form a vibrator element having an outer shape corresponding to the outer shape pattern,
wherein the vibrator element includes
a vibrator section that has a first principal surface that is a front surface, a second principal surface that is a rear surface opposite from the first principal surface, a first side surface that couples the first principal surface and the second principal surface to each other, and a second side surface that extends in a direction that intersects with a direction in which the first side surface extends,
a support section that is disposed at a distance from the vibrator section and has a first support side surface facing the first side surface of the vibrator section and a second support side surface extending in a direction that intersects with a direction in which the first support side surface extends, and
a linkage section that has a first linkage surface coupled to the first side surface and the first support side surface and a second linkage surface coupled to the second side surface and the second support side surface, and
the first linkage surface has a configuration in which at least one of a first section coupled to the first side surface and a second section coupled to the first support side surface has a curved surface.

9. The method for manufacturing a vibrator element according to claim 8,
wherein the etching is dry etching.
